(19) United States
(12) Patent Application Publication
(10) Pub. No.: US 2025/0344443 A1
(43) Pub. Date: Nov. 6, 2025

(54) CHANNEL DISCONNECTION BY BACKSIDE DIELECTRIC PLUG

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Oleg Gluschenkov, Tannersville, NY (US)

(21) Appl. No.: 18/652,257

(22) Filed: May 1, 2024

(51) Int. Cl. H01L 29/417; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 84/017; H10D 84/0186; H10D 84/038; H10D 84/85

(57) ABSTRACT

A semiconductor integrated circuit (IC) device includes a first source/drain region that is connected to a second source/drain region by one or more active channels, a backside dielectric plug that is connected to the second source/drain region, and a faux channel that is connected to the first source/drain region and that is connected to the backside dielectric plug. The backside dielectric plug adequately electrically isolates the faux channel from the second source/drain region. The fabrication of the backside dielectric plug may be utilized to modify transistors within a first region of the semiconductor IC device relative to transistors within a second region semiconductor IC device.

### BACKGROUND

In modern semiconductor integrated circuit (IC) device fabrication, transistor devices may be formed in different regions. For example, transistors may be formed within a low power region and within a high performance region of the same semiconductor IC device. In some instances, it may be beneficial for the transistors within one region to have structural differences relative to transistors within a different region, while largely utilizing the same formation stages to fabricate the different transistors.

### SUMMARY

In an embodiment of the disclosure, a semiconductor integrated circuit (IC) device is presented. The semiconductor IC device includes a first source/drain region that is connected to a second source/drain region by one or more active channels. The semiconductor IC device further includes a backside dielectric plug that is connected to the second source/drain region. The semiconductor IC device further includes a faux channel that is connected to the first source/drain region and that is connected to the backside dielectric plug.

In an embodiment of the disclosure, another semiconductor integrated circuit (IC) device is presented. The semiconductor IC device includes a first transistor within a first region of the semiconductor IC device. The first transistor includes a first source/drain region that is connected to a second source/drain region by a first group of active channels. The semiconductor IC device includes a second transistor within a second region of the semiconductor IC device. The second transistor includes a third source/drain region that is connected to a fourth source/drain region by a second group of active channels that has fewer active channels relative to the first group of active channels. The second transistor further includes a backside dielectric plug that is connected to the fourth source/drain region and a faux channel that is connected to the third source/drain region and that is connected to the backside dielectric plug.

In another embodiment of the disclosure, a semiconductor integrated circuit (IC) device fabrication method is presented. The method includes forming a backside dielectric plug opening within a backside interlayer dielectric that exposes a backside contact placeholder. The method further includes exposing a source/drain region by removing the backside contact placeholder. The method further includes removing a backside portion of the exposed source/drain region, wherein a bottom surface of the source/drain region is above a top surface of a bottommost channel. The method further includes forming a backside dielectric plug within the backside dielectric plug opening, against the source/drain region, and against the bottommost channel, wherein the backside dielectric plug electrically isolates the bottommost channel from the source/drain region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of an illustrative semiconductor IC device that includes a backside dielectric plug that at least partially disconnects a channel between a source and a drain, according to one or more embodiments of the disclosure.

FIG. 2A depicts a partial structure top-down view of an illustrative semiconductor IC device that is formed to include a backside dielectric plug that disconnects an active nanolayer between source/drain regions, according to one or more embodiments of the disclosure.

FIG. 2B through FIG. 10 depict various fabrication structure cross-section views of an illustrative semiconductor IC device that is formed to include a backside dielectric plug that disconnects an active nanolayer between source/drain regions, according to one or more embodiments of the disclosure.

FIG. 11 depicts a cross-section view of an illustrative backside dielectric plug that is directly coupled to a backside contact, according to one or more embodiments of the disclosure.

FIG. 12 depicts a method of fabricating a semiconductor IC device with a backside dielectric plug that disconnects an active nanolayer between source/drain regions, according to one or more embodiments of the disclosure.

### DETAILED DESCRIPTION

The embodiments of the present disclosure relate to fabrication methods and resulting structures for semiconductor IC devices. More specifically, the present disclosure relates to fabrication methods and resulting semiconductor integrated circuit (IC) devices that include a backside dielectric plug that is formed to adequately electrically isolate, or disconnect, a portion of a channel (e.g., one or more nanolayer channels) from either its previously associated source region or drain region. This scheme may be utilized to modify transistors within a first region, such as a low power device region of a semiconductor IC device relative to transistors within a second region, such as a high performance region of the same semiconductor IC device while largely utilizing the same fabrication stages to form the various transistors.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanolayer, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for improved channel electrostatics control.

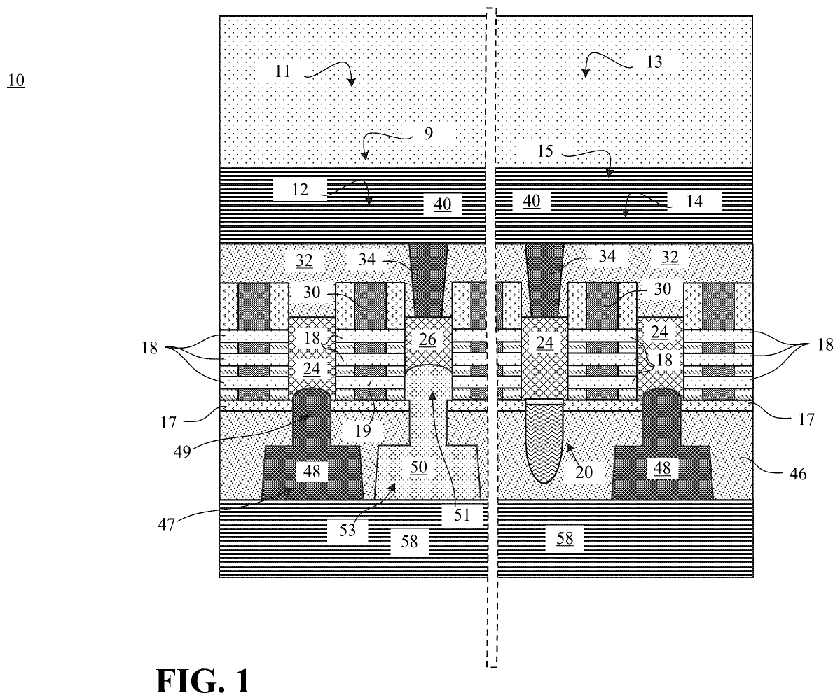

Referring now to the figures, FIG. 1 depicts a cross-sectional view of an illustrative semiconductor integrated circuit (IC) device 10. In an embodiment of the disclosure, the semiconductor IC device 10 includes a first source/drain region 24 that is connected to a second source/drain region 26 by one or more active channels 18. The semiconductor IC device 10 further includes a backside dielectric plug 50 that is connected to the second source/drain region 26. The semiconductor IC device 10 includes a faux channel 19 that is connected to the first source/drain region 24 and that is connected to the backside dielectric plug 50.

The faux channel 19 may be resultantly formed by the backside dielectric plug 50 adequately electrically isolating, or disconnecting, an otherwise active channel 18 from the second source/drain region 26. Because of this electrical isolation, adequate current does not flow through the otherwise active channel 18 between the first source/drain region 24 and the second source/drain region 26, and therefore the otherwise active channel 18 is referred to herein as faux channel 19.

The fabrication of the backside dielectric plug 50 may be congruent with similar fabrication techniques utilized to form backside contact(s) 48. In forming the faux channel 19, the channel (e.g., the number of active channels 18) between the first source/drain region 24 and the second source/drain region 26 may be reduced. This reduction may be beneficial for one or more transistors 12 in a region 11 of the semiconductor IC device 10, relative to transistors 14 within region 13 in the same semiconductor IC device 10.

In an example, the backside dielectric plug 50 electrically isolates the second source/drain region 26 from the faux channel 19. The electrical isolation prevents adequate current from flowing through the otherwise active channel 18 between the first source/drain region 24 and the second source/drain region 26 which resultantly converts the otherwise active channel 18 into the faux channel 19.

In an example, the semiconductor IC device 10 further includes a conductive frontside contact 34 that may be formed in a frontside interlayer dielectric (ILD) 32 and that is connected to the second source/drain region 26. This allows for potential to be applied to the second source/drain region 26 from a frontside back end of line (BEOL) network 40. This further allows for a backside contact placeholder 20 that would otherwise be located below the second source/drain region 26 to be removed and replaced by the backside dielectric plug 50.

In an example, the semiconductor IC device 10 further includes a conductive backside contact 48 that is connected to the first source/drain region 24. This allows for potential to be applied to the first source/drain region 24 from a backside BEOL network 58. The fabrication of the backside dielectric plug 50 may be congruent with similar fabrication techniques utilized to form the backside contact 48.

In an example, the semiconductor IC device 10 further includes a gate 30 that is connected to the one or more active channels 18 and that is connected to the faux channel 19. The gate 30 may be connected to the frontside BEOL network 40 or the BEOL network 58 that may supply a potential thereto which may control whether the current path between the first source/drain region 24 and the second source/drain region 26 through the one or more active channels 18 is an open circuit (“off”) or a resistive path (“on”).

In an example, the one or more active channels 18 are vertically in line with the faux channel 19. This may result from the fabrication of the active channels 18 and electrically isolating one or more of the active channels 18 from the second source/drain region 26, thus converting the electrically isolated one or more of the active channels 18 into faux channel(s) 19.

In an example, the faux channel 19 is below the one or more active channels 18. This may result from the backside dielectric plug 50 being formed from the backside of the semiconductor IC device 10 and thus electrically isolating the bottommost active channel(s) 18 from the second source/drain region 26.

In an example, a bottom surface of the second source/drain region 26 is above a bottom surface of the first source/drain region 24. This may result in removing a lower portion of the second source/drain region 26 by way of a backside dielectric plug opening, prior to the formation of the backside dielectric plug 50 therein.

In an example, the semiconductor IC device 10 further includes an isolation layer 17 between the gate 30 and a backside ILD 46 and wherein the backside dielectric plug 50 is composed of a first dielectric material and the backside ILD 46 is composed of a second dielectric material that is different from the first dielectric material. This may allow for material selection of the backside dielectric plug 50 to provide for structural benefits the semiconductor IC device 10. For example, a material may be selected so that backside dielectric plug 50 may reduce shorting risks by stopping or limiting metal propagation, so that backside dielectric plug 50 may provide for increased electrical isolation between conductive structures, or the like.

In an example, the backside ILD 46 is between a narrow region 49 of the conductive backside contact 48 and a narrow region 51 of the backside dielectric plug 50. This may result from a respective illustrative “T” shape of the conductive backside contact 48 and backside dielectric plug 50, the backside ILD 46 being formed upon the backside of the semiconductor IC device 10 prior to the formation of the conductive backside contact 48 or backside dielectric plug 50, and a wide region 47 of the conductive backside contact 48 and a wide region 53 of the backside dielectric plug 50 being located below the isolation layer 17.

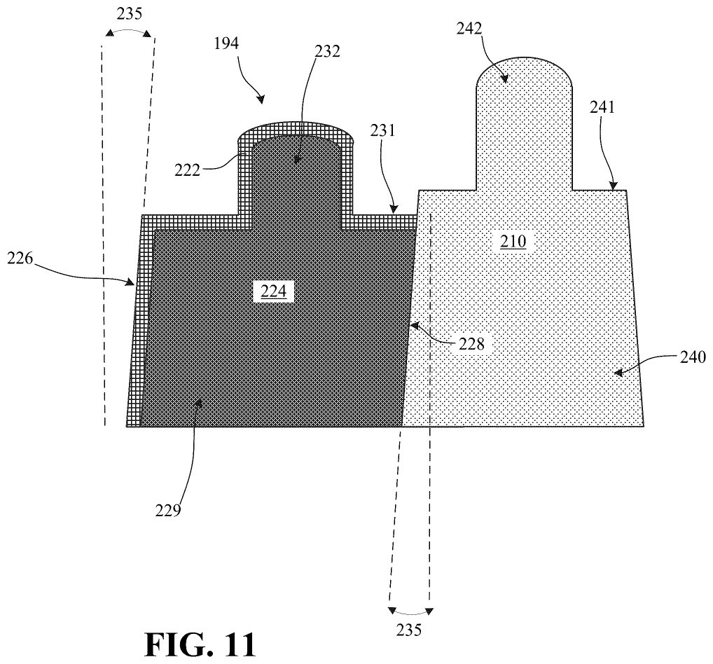

In an example, a wide region 47 of the conductive backside contact 48 is directly coupled to a wide region 53 of the backside dielectric plug 50 (not depicted in FIG. 1, but similarly depicted in FIG. 11). This may be the result of the backside dielectric plug opening cutting and/or exposing a portion of the conductive backside contact 48 and forming the backside dielectric plug 50 in direct contact against the conductive backside contact 48.

In an embodiment of the disclosure, semiconductor IC device 10 includes a first transistor 14 within a first region 13 and a second transistor 12 within a second region 11 of the semiconductor IC device 10. The first transistor 14 includes a first source/drain region 24 that is connected to a second source/drain region 24 by a first group 15 of active channels 18. The second transistor 12 includes a third source/drain region 24 that is connected to a fourth source/drain region 26 by a second group 9 of active channels 18 that has fewer active channels 18 relative to the first group 15 of active channels 18. The second transistor 12 further includes a backside dielectric plug 50 that is connected to the fourth source/drain region 26 and a faux channel 19 that is connected to the third source/drain region 24 and that is connected to the backside dielectric plug 50.

The fabrication of the backside dielectric plug 50 may be congruent with similar fabrication techniques utilized to form backside contact(s) 48. The relative reduced number of active channels between the first group 15 and the second group 9 may be the result of turning one or more of the active channels 18 in the second group 9 into faux channel(s) 19. This reduction of active channels 18 in the second group 9 may be beneficial for one or more transistors 12 in the region 11 of the semiconductor IC device 5, relative to transistor(s) 14 within region 13.

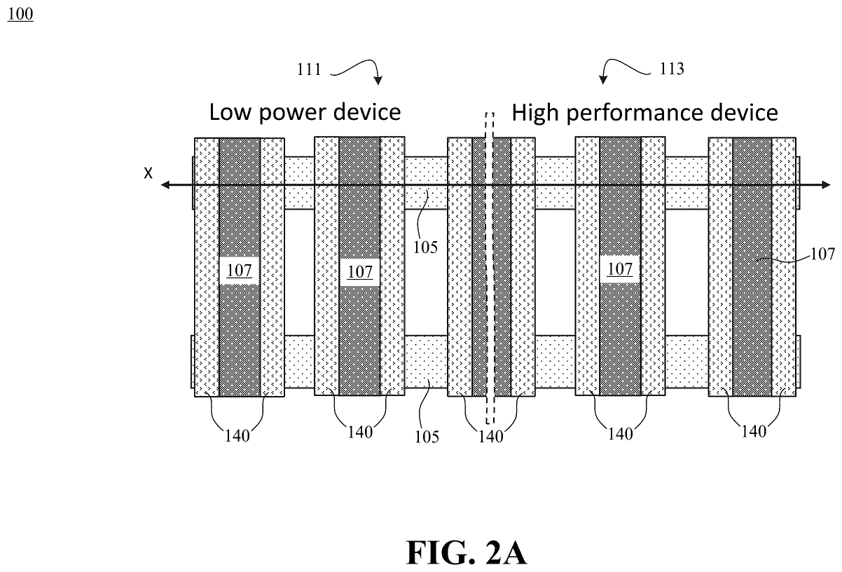

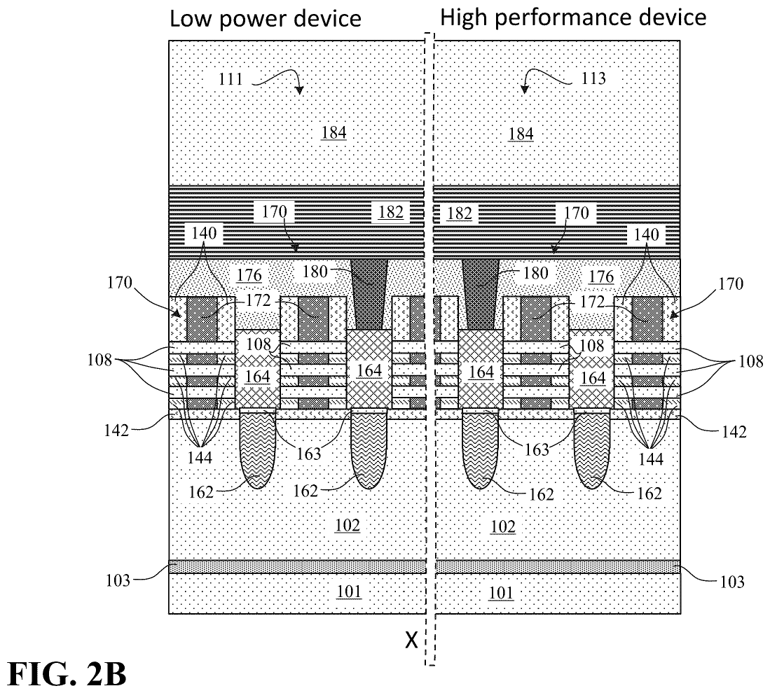

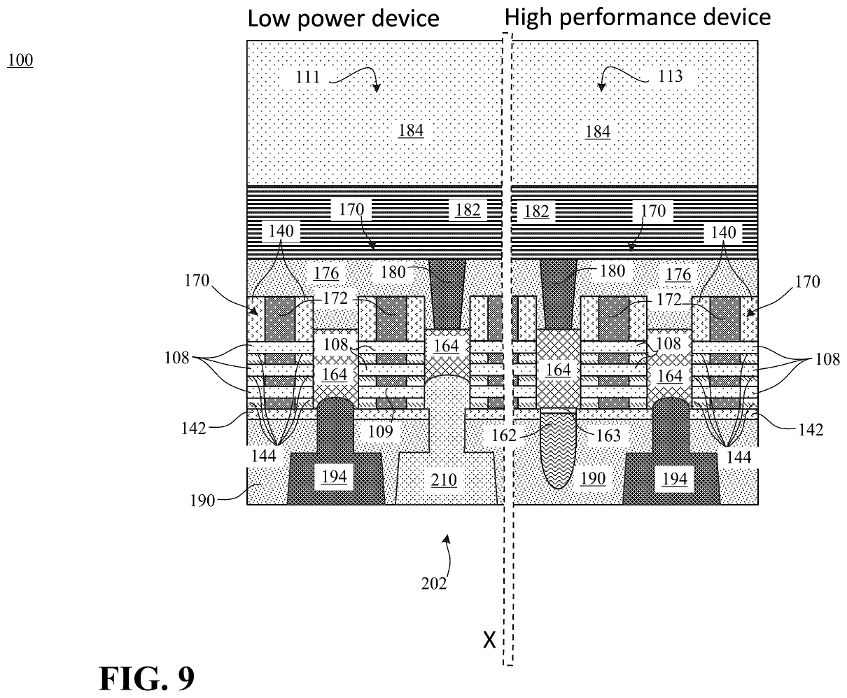

FIG. 2A depicts a partial structural top-down view of an illustrative semiconductor IC device 100 that is formed to include a backside dielectric plug 210 (depicted in FIG. 9) that disconnects an active nanolayer 108 between source/drain regions 164, thus forming a faux channel 109. Semiconductor IC device 100 includes a low power device region 111 and a high performance device region 113.

In examples, low power device region 111 includes one or more transistors that include fewer active nanolayer 108 channel(s) relative to the transistors in high performance device region 113 or in other words low power device region 111 includes one or more transistors that include more faux channel(s) 109 relative to the transistors in high performance device region 113. In these examples, high performance device region 113 includes transistors that include more active nanolayer 108 channel(s) relative to one or more transistors in low performance device region 111.

The present depiction of semiconductor IC device 100 also shows multiple nanolayer rows 105 and multiple gate structures 107 (e.g., sacrificial gate structures or replacement gate structures depending upon a reference stage semiconductor IC device 100 of fabrication). Also depicted are gate spacers 140 around the gate structures 107.

FIG. 2A also depicts a cross-sectional plane X, which is a vertical plane across various structures 107 through a nanolayer row 105. The nanolayer rows 105 may define respective active areas of the semiconductor IC device 100. For clarity, at the stage of semiconductor IC device 100 fabrication when nanolayer rows 105 are present, the gate structures 107 may be sacrificial gate structures and when associated active areas are present, the gate structures 107 may be replacement gate structures. The cross-sectional plane X establishes the plane of the cross-sectional views of the semiconductor IC device 100 depicted in FIG. 2B through FIG. 10.

FIG. 2B depicts a cross-sectional initial fabrication view of the semiconductor IC device 100 that is ultimately formed to include a backside dielectric plug 210 that disconnects an active nanolayer 108 between source/drain regions 164, thus forming a faux channel 109 (shown in the fabrication stage depicted in FIG. 9). At this initial fabrication stage depicted in FIG. 2B, the semiconductor IC device 100 may include a lower substrate 101, an etch stop layer 103, an upper substrate 102, STI regions (not shown in the depicted cross-section), backside contact placeholders 162, barrier layers 163, source/drain (S/D) regions 164, a frontside ILD 176, one or more frontside contact(s) 180, a frontside BEOL network 182, and a carrier wafer 184.

For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 2B, such associated component numeral is expressly utilized. Otherwise, when components are referenced in the illustrative methodology that are not depicted in FIG. 2B, a component numeral is not denoted.

The illustrative semiconductor IC device 100 may be formed by initially providing or forming a substrate structure. The substrate structure may be a bulk-semiconductor substrate. In one example, the bulk-semiconductor substrate may be a silicon-containing material. In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any suitable semiconductor material(s), and the etch stop layer 103 may be a dielectric material with etch selectivity to one or both upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101, and the upper substrate 102 may be composed of Si and may be epitaxially grown from the top surface of etch stop layer 103.

Next, the illustrative semiconductor IC device 100 may be formed by forming nanolayers over the substrate structure by forming a bottommost sacrificial nanolayer (not shown) and by forming a series of alternating sacrificial nanolayers (not shown) and active nanolayers 108, thereupon. In certain examples, the bottommost sacrificial nanolayer is initially formed directly on an upper surface of the substrate structure. In other examples, certain layer(s) may be formed between the upper surface of the substrate structure and the bottommost sacrificial nanolayer. In an example, the bottommost sacrificial nanolayer may be formed by epitaxially growing a SiGe layer with a relatively high percentage of Ge, ranging from 50% to 70%. The bottommost sacrificial nanolayer may have etch selectivity relative to the sacrificial nanolayers and active nanolayers 108.

The nanolayers may be further formed by fabricating the alternating series of sacrificial nanolayers, such as SiGe sacrificial nanolayers, and active nanolayers 108, such as Si nanolayers, upon the bottommost sacrificial nanolayer. The sacrificial nanolayers can have Ge percentages ranging from 20% to 45%. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers 108 are formed by epitaxial growth, such nanolayers can be formed by any appropriate deposition mechanism.

Further, in the depicted fabrication stages, the nanolayers may be patterned into nanolayer rows 105 (depicted in FIG. 2A) and shallow trench isolation (STI) regions (not shown) may be formed within the substrate structure adjacent to the nanolayer rows 105.

The one or more nanolayer rows 105 may be formed by lithography and etching techniques. Following the nanolayer row 105 patterning process, the one or more nanolayer rows 105 are formed. The removal of undesired portion(s) of the nanolayers may further remove undesired portions of substrate structure that are adjacent to respective footprints of nanolayer rows 105 to form STI region openings. A STI region (not shown) may be formed upon and/or within the substrate structure within respective STI region openings. The STI regions may be formed by depositing electrical dielectric material(s) within respective STI region opening(s) that are adjacent to the one or more nanolayer rows 105. A top surface of the one or more STI regions may be initially coplanar with or below a top surface of the substrate structure.

The illustrated semiconductor IC device 100 may be further fabricated by forming sacrificial gate structures (not shown). The sacrificial gate structures may include a sacrificial gate liner, a sacrificial gate, and a sacrificial gate cap. The sacrificial gate structures may be formed by initially depositing a sacrificial gate liner layer (e.g., a dielectric, oxide, or the like) upon the one or more STI regions and upon and around the one or more nanolayer rows 105. The sacrificial gate structures may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 105. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner, the sacrificial gate, and the sacrificial gate cap, respectively, of each of the one or more sacrificial gate structures.

The illustrated semiconductor IC device 100 may be further fabricated by removing the bottommost sacrificial nanolayer. The bottommost sacrificial nanolayer may be removed by a wet etch utilizing an etchant that targets the material of the bottommost sacrificial nanolayer selective to the respective material(s) of the sacrificial nanolayers, the active nanolayers 108, the STI region(s), and/or sacrificial gate structures, as appropriate. The etch may be timed or otherwise controlled to effectively remove the bottommost sacrificial nanolayer while substantially retaining the sacrificial nanolayers, the active nanolayers 108, the STI region(s), and the sacrificial gate structures, etc. The removal of bottommost sacrificial nanolayer may form a bottom isolation cavity between the substrate structure and the lowest sacrificial nanolayer.

The illustrated semiconductor IC device 100 may be further fabricated by forming gate spacers 140 around the sacrificial gate structures and by forming a bottom isolation 142 in place of the removed bottommost sacrificial nanolayer within the nanolayer rows 105.

The bottom isolation 142 and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity(ies) formed by the removal of the bottommost sacrificial nanolayer, upon STI regions, upon around the one or more sacrificial gate structures, and upon and around the one or more nanolayer stack(s). Subsequently, undesired portions of dielectric material may be removed while desired portions the dielectric material may be retained and thereby form the bottom isolation 142 and the gate spacer(s) 140.

For clarity, semiconductor IC device 100, can also be fabricated by alternative operations that result in the absence of bottom isolation 142 or operations that retain the bottommost sacrificial nanolayer while the gate spacer(s) 140 are formed. This bottommost sacrificial nanolayer may be subsequently removed during the removal of the sacrificial nanolayers and the bottom isolation 142 may be formed along with the inner spacers 144.

The illustrated semiconductor IC device 100 may be further fabricated by forming recesses within the one or more nanolayer rows 105 between gate spacers 140 of neighboring sacrificial gate structures. In other words, a single nanolayer row 105 may be separated, by one or more recesses, into multiple nanolayer stacks each located underneath a portion of respective sacrificial gate structure and associated gate spacers 140.

The one or more recesses may be formed between adjacent sacrificial gate structures by removing respective portions of the sacrificial nanolayers and active nanolayers 108 that are between gate spacers 140 of adjacent or neighboring sacrificial gate structures. The one or more S/D recesses may be formed to a depth to stop at the top surface of the bottom isolation 142, or the like. The undesired portions of sacrificial nanolayers, active nanolayers 108, and the like, may be removed by etching or other subtractive removal techniques. As the gate spacers 140 and the sacrificial gate structures may be utilized to protect the underlying portions of sacrificial nanolayers, active nanolayers 108, and bottom isolation 142 (if present), respective sidewalls of the nanolayer stacks may be substantially vertical and substantially coplanar with the outer sidewalls of the gate spacers 140 there above.

As used herein, “substantially vertical” sidewalls deviate from a direction normal to a major surface (e.g., top surface, etc.) of the substrate 102 by less than 5°, e.g., 0°, 1°, 2°, 3°, 4°, or 5°, including ranges between any of the foregoing values.

The illustrated semiconductor IC device 100 may be further fabricated by forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure 170 that is formed in place of one sacrificial gate structure. When the sacrificial nanolayers are composed of SiGe and when active nanolayers 108 are Si, the directional RIE can use a boron-based chemistry or a chlorine-based chemistry, for example, which recesses or removes the exposed end portions of sacrificial nanolayers (e.g., end portions of sacrificial nanolayers generally below spacer 140) selective to the Si active nanolayers 108. In alternative implementations when sacrificial nanolayers are not SiGe and when active nanolayers 108 are not Si, the directional etch of the sacrificial nanolayers may generally be selective to the active nanolayers 108, gate spacers 140, STI regions, and/or substrate structure.

The illustrated semiconductor IC device 100 may be further fabricated by forming a respective inner spacer 144 within each indent. The one or more inner spacers 144 can be formed by ALD or CVD or any other suitable deposition technique that deposits a dielectric material within the indent(s), thereby forming the inner spacer(s). In some examples, the inner spacer(s) 144 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, a directional etch process is performed to create substantially vertical sidewalls of the inner spacer(s) 144 that are coplanar with the substantially vertical sidewalls of the active nanolayers 108, of the gate spacers 140, or the like.

The illustrated semiconductor IC device 100 may be further fabricated by forming one or more backside contact placeholders 162 within the substrate structure in between adjacent sacrificial gate structures within a respective opening. In one example, a respective backside contact placeholder 162 may be formed in all opening location(s), such that a respective backside contact placeholder 162 is located underneath each S/D region 164.

If the recesses are not of sufficient depth, the one or more backside contact placeholders 162 may be formed by forming one or more backside contact placeholder openings within the substrate structure generally in between adjacent sacrificial gate structures and below the prior respective one or more recesses. The one or more backside contact placeholders 162 may be further formed by epitaxially growing an epitaxial material from exposed substrate structure surface(s) within the one or more backside contact placeholder(s) openings. In an example, the epitaxial material of the one or more backside contact placeholders 162 may be chosen to be etch selective to the material of the S/D region(s) 164, the material of the upper substrate 102, or the like.

In an example, as depicted, a barrier layer 163 may be formed upon the backside contact placeholder 162 within the one or more backside contact placeholder(s) cavities. The barrier layer 163 may be utilized to help protect or mask the associated backside contact placeholder 162 during the etching process(es). The barrier layer(s) 163 may be epitaxially grown. For example, the one or more backside contact placeholders 162 may be SiGe and the barrier layer(s) 163 may be Si.

The illustrated semiconductor IC device 100 may be further fabricated by forming one or more respective S/D regions 164 upon a respective backside contact placeholder 162 or barrier layer 163 (if present). For example, p-doped S/D regions 164 may be formed in a first formation sequence and then n-doped S/D regions 164 may be formed in a second formation sequence, or vice versa.

Each S/D region 164 may form either a source or a drain, respectively, of a respective transistor and is connected to respective end surfaces of the active nanolayers 108 of one or more nanolayer stacks. Each S/D region 164 is composed of a semiconductor material and a dopant. As used herein, a “source/drain” region can be a source region or a drain region depending on subsequent wiring and application of voltages during operation of the applicable transistor.

The semiconductor material that provides each of the S/D regions 164 may be composed of one of the semiconductor materials mentioned above for the semiconductor structure. For example, the semiconductor material that provides the S/D region 164 can be compositionally the same, or compositionally different from each active nanolayer 108. The dopant that is present in the S/D regions 164 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 164 are referred to herein as being p-doped and when the semiconductor material is doped with a n-type dopant, the resulting S/D regions 164 are referred to herein as being n-doped.

The S/D regions 164 may be epitaxially grown or formed. In some examples, the S/D regions 164 are formed by in-situ doped epitaxial growth. The use of an in-situ doping process is merely an example. For instance, one may instead employ an ex-situ process to introduce dopants into the S/D regions 164. Other doping techniques can be used to incorporate dopants in the S/D regions 164.

In some examples, the epitaxial growth that forms the S/D region 164 occurs or is promoted from the top surface of upper substrate 102, from the upper surface of backside contact placeholders 162 (or barrier layer 163 thereupon), from the exposed sidewalls of the active nanolayers 108, or the like, while epitaxial growth may be limited or does not occur from neighboring STI regions.

The illustrated semiconductor IC device 100 may be further fabricated by forming interlayer dielectric (ILD) 176. For example, a blanket ILD 176 may be deposited over the S/D region(s) 164, over the STI region(s), over the sacrificial gate structures, and over the gate spacers 140, and the like.

The ILD 176 can be any suitable dielectric material, such as, for example, porous silicates, carbon doped oxides, silicon dioxides, silicon nitrides, silicon oxynitrides, OPL, or other dielectric materials. Subsequently, a planarization process, such as a CMP, may be performed to remove excess ILD 176 material and to remove the sacrificial gate caps of the sacrificial gate structures, thereby exposing the sacrificial gate thereunder.

The illustrated semiconductor IC device 100 may be further fabricated by removing the sacrificial gate structures and then forming replacement gate structures 170 in place thereof. The sacrificial gate structures may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures selective to the active nanolayers 108, inner spacers 144, gate spacers 140, the bottom isolation 142, STI regions, or the like.

Next, or simultaneously, the active nanolayers 108 may be released by removing the sacrificial nanolayers within the nanolayer stacks. The sacrificial nanolayers may be removed by a removal technique, such as one or more series of etches. After the removal of sacrificial nanolayers, void spaces may be formed above and/or below the active nanolayers 108.

The illustrated semiconductor IC device 100 may be further fabricated by forming a replacement gate structure 170 in place of the removed sacrificial gate structures around the active nanolayers 108, upon STI region(s), upon the bottom isolation 142, etc.

Replacement gate structure(s) 170 may be formed by initially forming an interfacial layer on the gate spacers 140, on the active nanolayers 108, on the bottom isolation 142, on the inner spacers 144, etc. that are interior to and/or upon the respective surfaces interior to the opening created by the removal of the sacrificial gate structure and the releasing of the active nanolayers 108.

The replacement gate structure(s) 170 may be further formed by depositing a high-κ layer to cover the exposed surfaces of the interfacial layer. A high-κ material is a material with a higher dielectric constant than that of SiO₂. The high-κ layer can include a single layer or multiple layers, such as metal layer, liner layer, wetting layer, and adhesion layer. The replacement gate structure(s) 170 may be further formed by depositing a work function (WF) gate upon the high-κ layer. The WF gate can be comprised of a conductor or metal. In general, the WF gate sets the threshold voltage (Vt) of the device. The high-κ layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The replacement gate structure(s) 170 may be further formed by depositing a conductive gate 172. In an example, when none of the previous replacement gate material(s) are utilized in the replacement gate structures, the conductive gate may be formed upon the same or similar surfaces as those upon which the interfacial layer, described above, may be formed. In other examples, when one or more of the interfacial layer, the high-κ layer, the WF gate, or the like, are or are not utilized in the replacement gate structures, the conductive gate may be formed upon the most recent structural formation thereof.

The conductive gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. After the replacement gate structure 170 formation, the top surface of the semiconductor IC device 100 may be planarized by a planarization technique such as a CMP, mechanical grinding process, or the like.

The illustrated semiconductor IC device 100 may be further fabricated by forming a frontside contact ILD (shown as the same material as ILD 176). The frontside contact ILD may be formed upon respective top surfaces of replacement gate structure(s) 170, ILD 176, and gate spacers 140. The frontside contact ILD may be formed by depositing a dielectric material, such as, for example, porous silicates, carbon doped oxides, silicon dioxides, silicon nitrides, silicon oxynitrides, or other dielectric materials.

The illustrated semiconductor IC device 100 may be further fabricated by forming frontside contacts 180 within the frontside contact ILD and the ILD 176. The frontside contacts 180 may be formed by patterning respective frontside contact openings within the ILD layer(s), respectively, from the frontside (i.e., from above the semiconductor IC device 100, as depicted, downward to respective structures thereof). The frontside contacts 180 may be in direct or indirect physical and electrical contact and/or may physically meld with respective material(s) of one or more regions of the semiconductor IC device 100.

The frontside contact(s) 180 may be formed by depositing conductive material such as metal into the respective frontside contact opening(s). In an example, frontside contact(s) 180 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 180 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

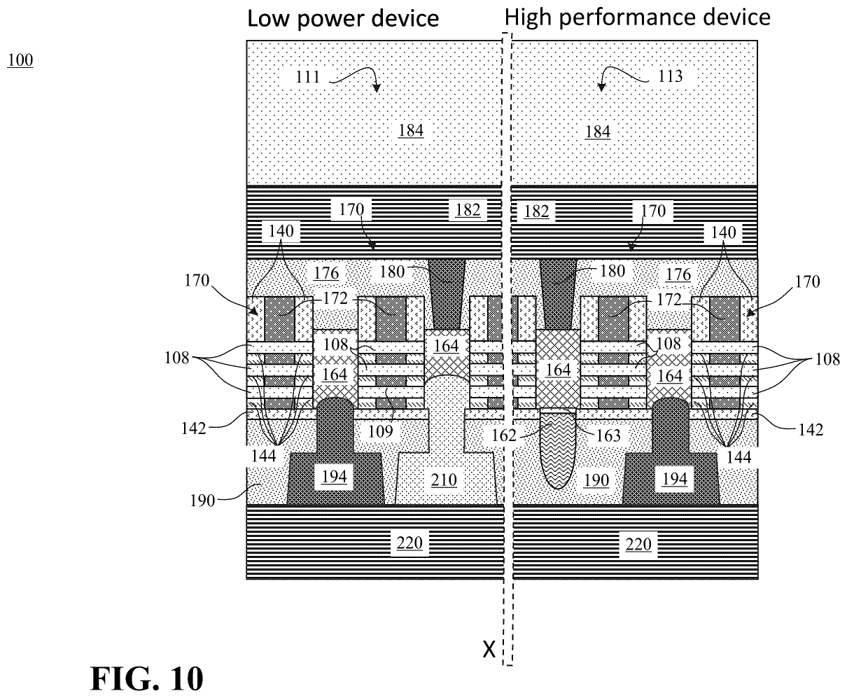

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 182 is formed on the frontside of the semiconductor device 100. Subsequently, a backside BEOL network 220, as depicted in FIG. 10, is formed.

In the depicted example, the frontside BEOL network 182 is formed over the contact ILD and upon the frontside contacts 180. Respective wires within the frontside BEOL network 182 may be electrically connected to the one or more S/D regions 164, to the one or more replacement gate structure(s) 170, or the like, by a respective frontside contact(s) 180. For example, respective wire(s) within the frontside BEOL network 182 may be electrically connected to appropriate S/D regions 164 by a frontside contact 180, and another different group of respective wire(s) within the frontside BEOL network 182 may be electrically connected to appropriate replacement gate structures 170, etc.

The frontside BEOL network 182 can include one or more interconnect dielectric material layers (including one of the dielectric materials mentioned above for the frontside ILD 176) and contains metal wires (the metal wires can be composed of any electrically conductive metal or electrically conductive metal alloy) embedded therein. In some embodiments, the frontside metal wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by bonding carrier wafer 184 to the frontside BEOL network 182. The carrier wafer 184 can include one of the semiconductor materials mentioned above for the semiconductor structure and the carrier wafer 184 may be attached to the semiconductor IC device 100 by a wafer-to-wafer bonding technique.

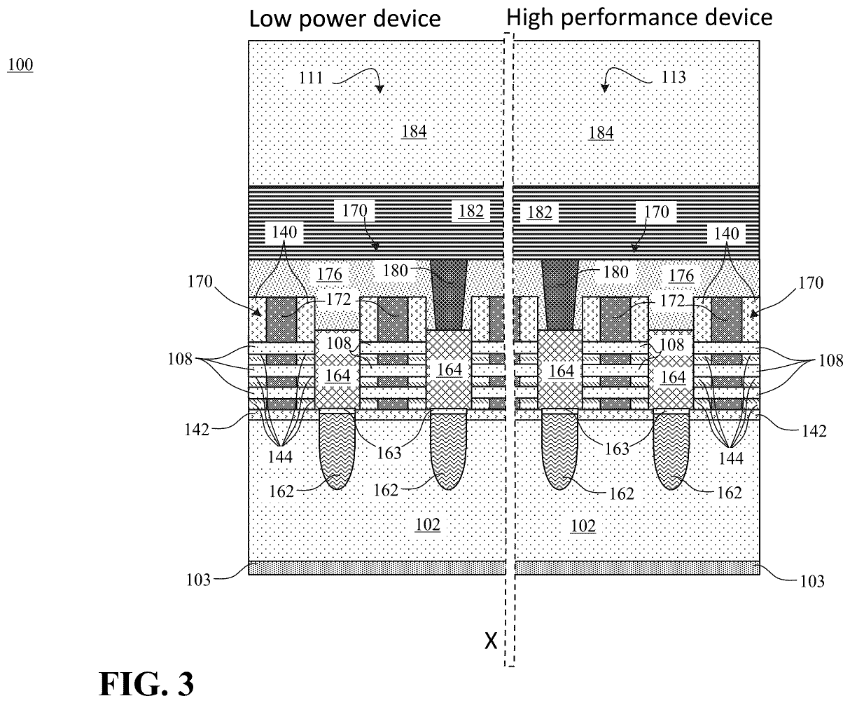

FIG. 3 depicts cross-sectional views of the semiconductor IC device 100 after fabrication operations, in accordance with embodiments of the present disclosure. In the depicted fabrication stages, the substrate structure may be recessed. For example, the lower substrate 101 may be removed.

The substrate structure may be recessed by flipping the semiconductor IC device 100 and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

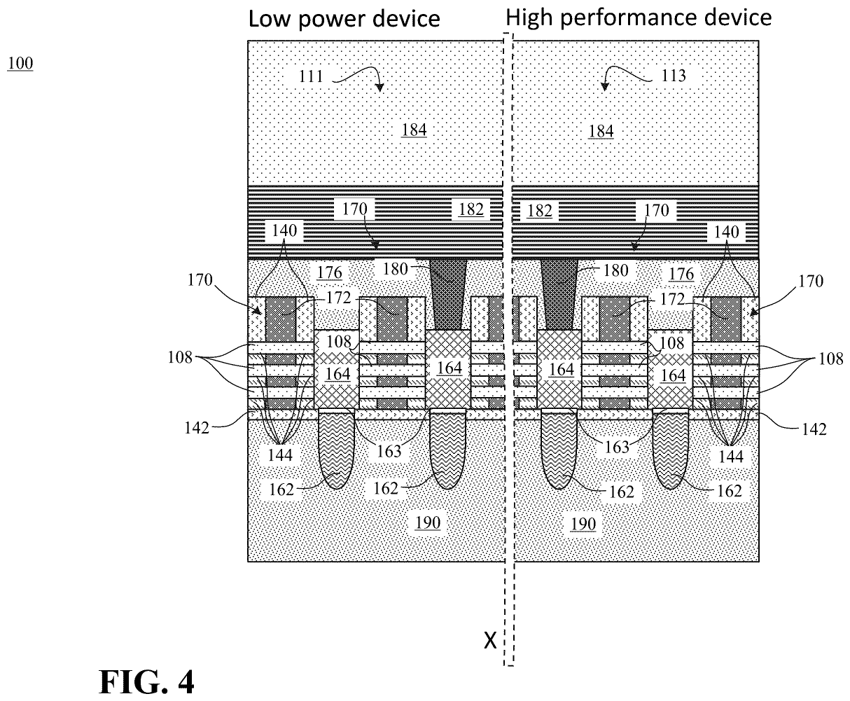

FIG. 4 depicts cross-sectional views of the semiconductor IC device 100 after fabrication operations, in accordance with embodiments of the present disclosure. In the depicted fabrication stages, the substrate structure may be further recessed. For example, the etch stop layer 103 and the upper substrate 102 may be removed. Further, in the depicted fabrication stages, a backside interlayer dielectric (ILD) may be formed. For example, backside ILD 190 may be formed.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

The upper substrate 102 may be removed by an appropriate substrative removal technique, such as an etch. The etch may be timed or otherwise controlled to remove the material of substrate 102 selective to the STI regions, to the backside contact placeholders 162, to the bottom isolation 142, or the like.

The backside ILD 190 may be formed upon the backside contact placeholder(s) 162, upon the bottom isolation 142, upon the STI regions (not shown), etc. The backside ILD 190 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 190 can be utilized. The backside ILD 190 can be formed using, for example, CVD, PECVD, ALD, flowable CVD, spin-on dielectrics, or PVD.

In an example, as depicted, the material of the backside ILD 190 may be the same material as the frontside ILD 176. In alternative examples, the material of the backside ILD 190 may be chosen to achieve a predetermined electrical isolation metric that the dielectric material of frontside ILD 176 could not achieve, if utilized. For example, frontside ILD 176 may be silicon dioxide and the backside ILD 190 may be a low-K dielectric material.

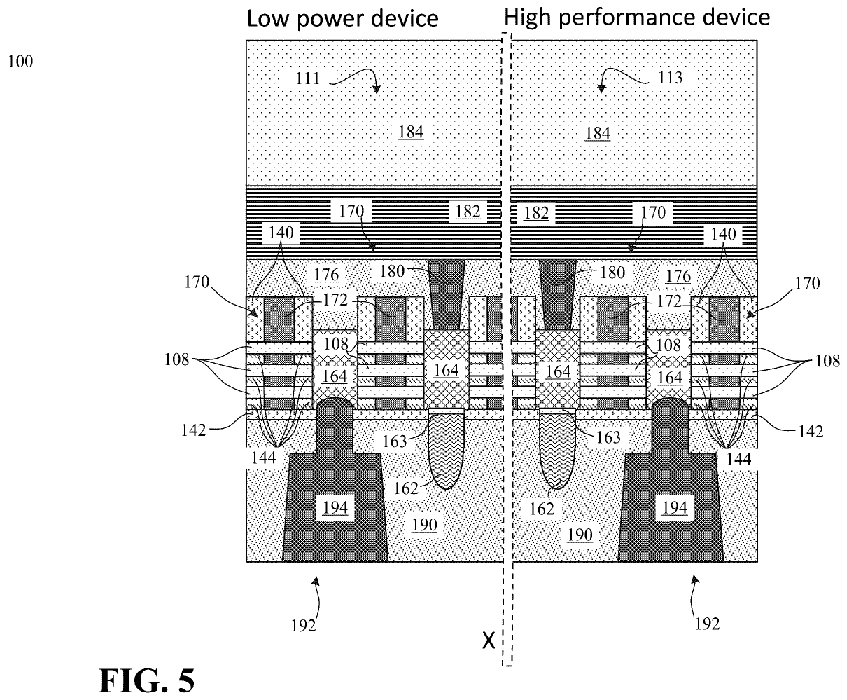

FIG. 5 depicts cross-sectional views of semiconductor IC device 100 shown after illustrative fabrication operation(s), in accordance with one or more embodiments. In the depicted fabrication stage, backside contact 194 may be formed.

A respective backside contact 194 may be formed by forming an associated backside contact opening 192. The backside contact opening(s) 192 may be formed by the same or shared lithography and etch process(es), or sequential lithography and etch processes. In such process(es), a mask (not shown) may be applied to the backside of the semiconductor IC device 100 and patterned. Openings in the patterned mask may sequentially expose the portion(s) of the underlying material(s) that are to be removed while other protected portions of semiconductor IC device 100 may be protected and retained.

The backside contact opening(s) 192 may be formed to expose the associated backside contact placeholder 162 there above (e.g., the backside contact placeholder 162 that is below a S/D region 164 that is not connected to the frontside BEOL network 182). The backside contact placeholder(s) 162 that are exposed by respective backside contact opening(s) 192 may be removed by a substrative removal technique, such as an etch. In one example, the applicable contact placeholder(s) 162 and barrier layer 163 associated therewith may be removed. In another example, the applicable contact placeholder(s) 162 is removed using the barrier layer 163 as an etch stop to protect the S/D region 164 there above. In this example, the barrier layer 163 may be retained and the S/D regions 164 are not exposed and/or gouged.

Alternatively, as depicted, the exposed S/D region(s) 164 may be exposed by the removal of the barrier layer 163 and at least partially gouged, or in other words, a lower portion of the exposed S/D region 164 is removed while an upper portion of the exposed S/D region(s) 164 is retained. The lower portion of the S/D region(s) 164 may be removed by a subtractive removal technique, such as an etch. A well surface of an associated gouging etch within the S/D region(s) 164 may be below the bottommost active semiconductor nanolayer 108, which ultimately results in a top surface of the backside contact 194 being below the bottommost active semiconductor nanolayer 108, as depicted.

Respective backside contact(s) 194 may be formed within a respective backside contact opening 192 against the associated S/D region 164 by depositing conductive material, such as metal, therein. In an example, backside contact(s) 194 may be simultaneously formed by depositing a liner, such as Ni, NiPt or Ti, etc. onto the backside of semiconductor IC device 100 and into the backside contact openings 192, depositing an adhesion liner, such as TiN, TaN, etc. upon the liner, and by depositing a conductive fill, such as Al, Ru, W, Co, Cu, etc. upon the adhesion liner.

Subsequently, a planarization process, such as a CMP, may expose a bottom surface of the backside ILD 190. As a result, the respective bottom surfaces of backside contact(s) 194 and backside ILD 190 may be substantially horizontal and/or substantially coplanar.

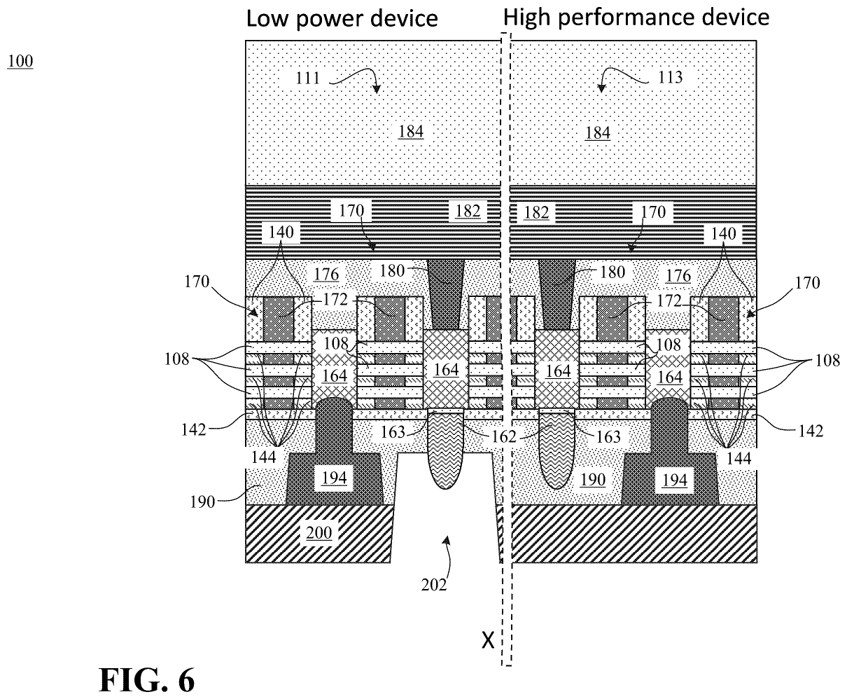

FIG. 6 depicts cross-sectional views of semiconductor IC device 100 shown after illustrative fabrication operation(s), in accordance with one or more embodiments. In the depicted fabrication stage, backside contact plug opening(s) 202 may be formed.

The backside contact plug opening(s) 202 may be formed by the same or shared lithography and etch process(es), or sequential lithography and etch processes. In such process(es), a mask 200 may be applied to the backside of the semiconductor IC device 100 and patterned. Openings in the patterned mask 200 may expose the portion(s) of the underlying material(s) that are to be removed while other protected portions of semiconductor IC device 100 may be protected and retained.

The backside contact plug opening(s) 202 may be formed to expose the associated backside contact placeholder 162 there above (e.g., the backside contact placeholder 162 that is below a S/D region 164 that is connected to the frontside BEOL network 182).

In an example, as depicted, the backside contact plug opening(s) 202 may be formed solely within the backside ILD 190 to expose the associated backside contact placeholder 162 there above. Alternatively, the backside contact plug opening(s) 202 may also partially remove a portion of an adjacent backside contact 194. In this example, a backside contact plug 210 formed within the backside contact plug opening(s) 202 may be in direct contact with the adjacent backside contact 194, as is depicted in FIG. 11.

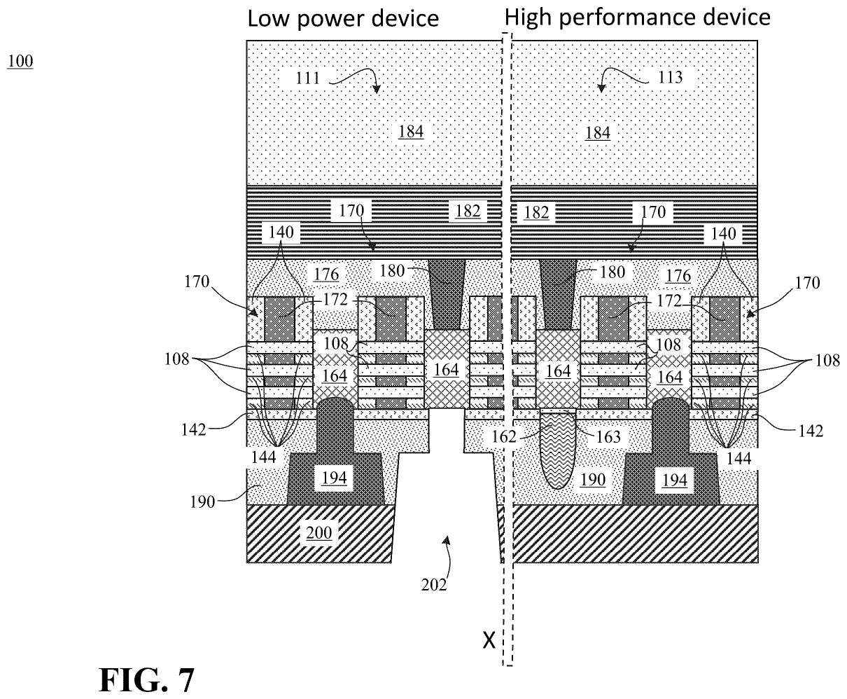

FIG. 7 depicts cross-sectional views of semiconductor IC device 100 shown after illustrative fabrication operation(s), in accordance with one or more embodiments. In the depicted fabrication stage, the associated S/D region may be exposed by removing the applicable backside contact placeholder 162 and barrier layer 163.

The backside contact placeholder(s) 162 that are exposed by respective backside contact plug opening(s) 202 may be removed by a substrative removal technique, such as an etch. In one example, the applicable contact placeholder(s) 162 and barrier layer 163 associated therewith may be removed.

The backside contact placeholder(s) 162 may be removed by a subtractive removal technique such as a wet etch. Upon removal of the backside contact placeholder(s) 162, the bottom surface the barrier layer 163 is exposed. The removal of the backside contact placeholder(s) 162 may be selective to the material of the barrier layer 163. For example, the backside contact placeholder(s) 162 are removed by an etch that utilizes the barrier layer 163 as the etch stop.

The barrier layer 163 may be removed by an appropriate substrative removal technique, such as an etch. The etch may be timed or otherwise controlled to remove the material of the barrier layer 163 selective to the bottom isolation 142, the associated S/D region 164, or the like, and may expose the backside of the associated S/D region 164.

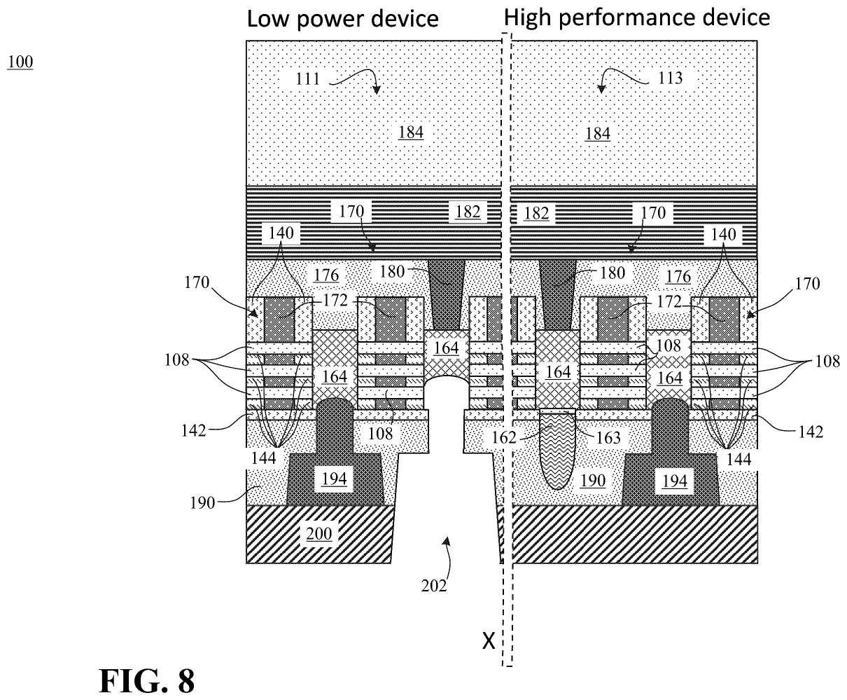

FIG. 8 depicts cross-sectional views of semiconductor IC device 100 shown after illustrative fabrication operation(s), in accordance with one or more embodiments. In the depicted fabrication stage, a lower portion of the associated S/D region 164 that is exposed by the backside contact plug opening(s) 202 may be removed.

The lower portion of the exposed S/D region 164 may be removed while an upper portion of the exposed S/D region(s) 164 is retained. The lower portion of the S/D region(s) 164 may be removed by a subtractive removal technique, such as an etch. The etch may be timed or otherwise controlled to remove the lower portion of the exposed S/D region 164 so that a well surface of an associated gouging etch within the S/D region(s) 164 is above at least the bottommost active semiconductor nanolayer 108. This may ultimately result in a top surface of the backside contact plug 210, as is depicted in FIG. 9, being above the bottommost active semiconductor nanolayer 108 and converting the bottommost active semiconductor nanolayer 108 to a faux channel.

For clarity, the etch may be timed or otherwise controlled to remove the lower portion of the exposed S/D region 164 so that a well surface of the associated gouging etch within the S/D region(s) 164 is above one or more other active semiconductor nanolayer(s) 108 that are above the bottommost active semiconductor nanolayer 108. This may ultimately result in a top surface of the backside contact plug 210, as depicted in FIG. 9, being above multiple active semiconductor nanolayers 108 and converting these multiple active semiconductor nanolayers 108 to faux channels.

FIG. 9 depicts cross-sectional views of semiconductor IC device 100 shown after illustrative fabrication operation(s), in accordance with one or more embodiments. In the depicted fabrication stage, a backside contact plug 210 may be formed within one backside contact plug opening 202.

The backside contact plug 210 may be formed by depositing a dielectric layer over the backside of the semiconductor IC device 100 and within the backside contact plug opening(s) 202. The backside contact plug 210 can be any suitable dielectric material, such as, for example, porous silicates, carbon doped oxides, silicon dioxides, silicon nitrides, silicon oxynitrides, or other dielectric materials. Subsequently, a planarization process, such as a CMP, may be performed to remove excess backside contact plug 210 material and to expose the backside contact(s) 194. As a result, the respective bottom surfaces of backside contact(s) 194, backside ILD 190, and backside contact plug 210 may be substantially horizontal and/or substantially coplanar.

For clarity, the material of the backside contact plug 210 may be a relatively different material compared to backside ILD 190, as depicted. This may be beneficial, for example, in situations where backside contact plug 210 is between backside contact 194 and relatively more robust (compared to that in which the material of backside ILD 190 provides) electrical isolation, barrier protection, or the like, between the backside contacts 194.

Since the etch that gouges the associated S/D region 164 may expose respective sidewalls of inner spacers 144 and sidewall(s) of the one or more active semiconductor nanolayers 108, the backside contact plug 210 may be formed directly upon the exposed of such sidewall(s). Particularly, the backside contact plug 210 is formed directly upon the sidewall(s) of the exposed active semiconductor nanolayer(s) 108 which, as a result, converts these exposed active semiconductor nanolayer(s) 108 into faux channels 109. For clarity, since one or more active semiconductor nanolayer(s) 108 of a series of vertically stacked or aligned active semiconductor nanolayers 108 may be converted into faux channel(s) 109, the faux channel(s) 109 are also vertically stacked or aligned (e.g., inline) with the series of other active semiconductor nanolayer(s) 108.

FIG. 10 depicts cross-sectional views of semiconductor IC device 100 shown after illustrative fabrication operation(s), in accordance with one or more embodiments. In the depicted fabrication stage, a backside BEOL network 220 may be formed.

The backside BEOL network 220, such as a backside power distribution network (BSPDN) may be formed upon the backside contact(s) 194, upon the backside ILD 190, and upon the backside contact plug(s) 210. The backside BEOL network 220 may include signal wires for signal routing and power wires for providing power potential (e.g., VDD, VSS, etc.). The backside BEOL network 220 may allow for the distribution of power wires and signal wires between both the frontside and backside of the semiconductor IC device. The backside BEOL network 220 may further allow for the full or partial decoupling of signal routing and/or power routing and/or allows for dividing or splitting power wires and/or signal wires between both the frontside and backside of the semiconductor IC device. By incorporating the backside BEOL network 220, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 220 may be electrically connected to the one or more S/D regions 164 by way of a particular backside contact 194. For example, a first backside wire within the backside BEOL network 220 may be electrically connected the backside contact 194, or the like.

The backside BEOL network 220 can include one or more interconnect dielectric material layers and contains backside conductive wires and/or interconnects, such as VIAs, embedded therein. In some embodiments, the backside wires within the backside BEOL network 220 are composed of Cu. The backside BEOL network 220 can include “x” numbers of backside metal levels, wherein “x” is an integer starting from 1. If not included in frontside BEOL network 182, backside BEOL network 220 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 220. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

Referring now to FIG. 11, a cross-section view of an illustrative backside contact 194 and backside contact plug 210 is depicted. In an example, the backside contact 194 includes one or more conductive liner layers 222 and a conductive filler 224. The conductive liner layer(s) 222 may be one or more of a barrier liner, an adhesion liner, or the like.

In an example, the backside contact plug 210 is directly coupled to the conductive filler 224 and directly coupled to the conductive liner layer(s) 222. The backside contact plug 210 being directly coupled to the backside contact 194 may be the result of the backside contact plug opening 202 exposing a portion of the conductive filler 224 of the first backside contact 194. In this example, the backside contact 194 may have substantially parallel sidewalls 226, 228, that may be angled or flared by an angle 235 from vertical. Such direct contact between the backside contact plug 210 and the backside contact 194 generally may reduce a horizontal pitch between components (e.g., two backside contacts) that may be beneficial for further semiconductor IC device scaling.

The sidewall 226 may be angled from vertical with an orientation such that the sidewall 226 is decreasing in distance away from vertical toward a bottom surface the backside contact 194. The sidewall 228 may be angled from vertical with an orientation such that the sidewall 226 is increasing in distance away from vertical toward the bottom surface the backside contact 194.

The backside contact 194 may include a lower portion 229 and an upper portion 232. A horizontal width in the depicted cross-section of the lower portion 229 is generally wider than a horizontal width of the upper portion 232. The lower portion 229 may have a top surface 231. Similarly, the backside contact plug 210 may include a lower portion 240 and an upper portion 242. A horizontal width in the depicted cross-section of the lower portion 240 is generally wider than a horizontal width of the upper portion 242. The lower portion 240 may have a top surface 241. In an example, the top surface 231 and the top surface 241 may be substantially coplanar, the top surface 231 may be above the top surface 241, or the top surface 231 may be below the top surface 241, as depicted. Further, a top surface of the upper portion 232 is below a top surface of the upper portion 242 which may be the result of the upper portion 242 being formed so as to be in direct contact with a faux channel 109, as depicted in FIG. 10.

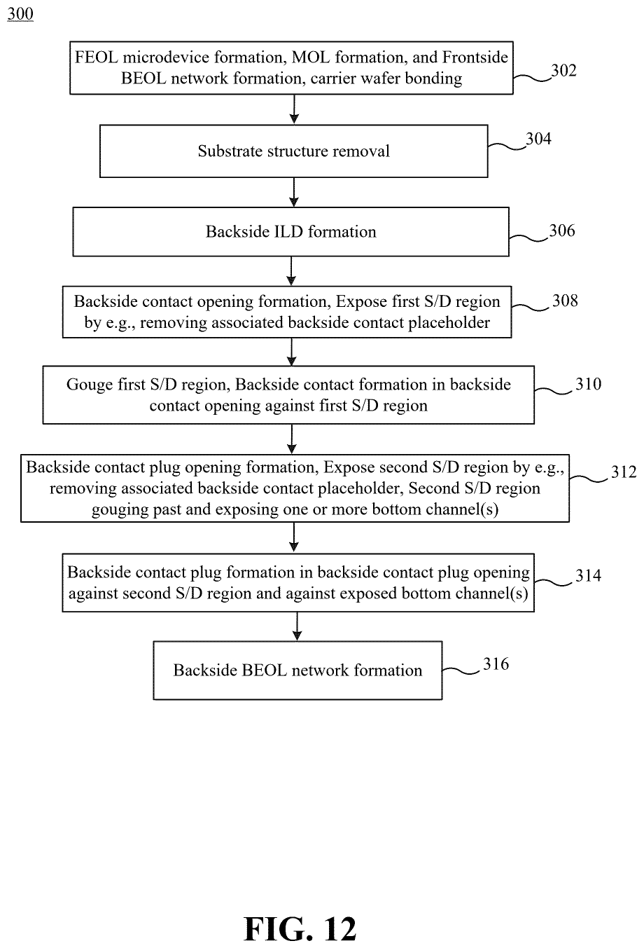

FIG. 12 depicts a flow diagram illustrating a method 300 to fabricate a semiconductor IC device, such as semiconductor IC device 100. The depicted fabrication operations of method 300 are illustratively depicted and described above with reference to one or more of FIG. 2B through FIG. 9 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming one or more front end of line (FEOL) microdevices, such as transistors, with forming middle of line (MOL) structures, such as frontside contact(s), with forming a frontside back end of line (BEOL) network, and with attaching a carrier wafer thereto. For example, one or more transistors are formed within the low power device region 111 and one or more transistors are formed within the high performance device region 113 of semiconductor IC device 100. Further, for example, one or more frontside contacts 180 are formed that may contact components or regions (such as S/D regions 164, replacement gate structures 170, etc.) of such transistors, the frontside BEOL network 182 is formed upon the one or more frontside contacts, and a carrier wafer 184 is bonded to the frontside BEOL network 182.

At block 304, the semiconductor IC device may be flipped (not depicted in the drawings), and a substrate structure associated with the FEOL microdevices may be partially removed. For example, the lower substrate 101, the etch stop layer 103, and the upper substrate 102 of the substrate structure may be removed.

At block 306, method 300 may continue with forming a backside ILD. For example, the backside ILD 190 may be deposited over the backside placeholders 162, over the bottom isolation 142, over STI region(s), or the like.

At block 308, method 300 may continue with forming a backside contact opening and exposing the associated S/D region. For example, backside contact opening(s) 192 may be formed within the backside ILD 190. The backside contact opening 192 may expose an associated backside contact placeholder 162 and the first S/D region 164 may be exposed by removing the backside contact placeholder 162, barrier layer 163, etc. by way of the backside contact opening 192.

At block 310, method 300 may continue with optionally gouging a first S/D region and with forming a backside contact against the first S/D region. Optionally, the first S/D region 164 may be further gouged by way of the backside contact opening 192 to a depth below the bottommost active semiconductor nanolayer(s). The backside contact 194 may be formed within the backside contact opening 192 against the first S/D region 164.

At block 312, method 300 may continue with forming a backside contact plug opening, with removing an associated backside contact placeholder, and with gouging a second S/D region past at least a bottommost active semiconductor nanolayer(s). For example, backside contact plug opening(s) 202 may be formed within the backside ILD 190. The backside contact plug opening(s) 202 may expose an associated backside contact placeholder 162. A second S/D region 164 may be exposed by removing the backside contact placeholder 162, barrier layer 163, etc. by way of the backside contact plug opening 202. The second S/D region 164 may be gouged by way of the backside contact plug opening 202 past at least the bottom active semiconductor nanolayer 108.

At block 314, method 300 may continue with forming a backside contact plug in the backside contact plug opening against the second S/D region and against the bottom active semiconductor nanolayer. For example, backside contact plug 210 is formed in the backside contact plug opening 202 against the second S/D region 164 and against the bottom active semiconductor nanolayer 108, thereby converting the bottom active semiconductor nanolayer 108 into a faux channel 109.

At block 316, method 300 may further continue with forming a backside BEOL network over the backside contact(s), over the backside ILD, and/or over the backside contact plug(s). For example, the backside BEOL network 220 may be formed over the backside ILD 190, over the backside contact(s) 194, and over the backside contact plug(s) 210.

For clarity, in an embodiment of the present disclosure, method 300 includes forming a backside dielectric plug opening within a backside interlayer dielectric that exposes a backside contact placeholder, exposing a source/drain region by removing the backside contact placeholder, removing a backside portion of the exposed source/drain region, wherein a bottom surface of the source/drain region is above a top surface of a bottommost channel, and forming a backside dielectric plug within the backside dielectric plug opening, against the source/drain region, and against the bottommost channel, wherein the backside dielectric plug electrically isolates the bottommost channel from the source/drain region.

Because the backside dielectric plug electrically isolates the bottommost channel from the source/drain region, a faux channel may be resultantly formed. The fabrication of the backside dielectric plug may be congruent with similar fabrication techniques utilized to form backside contact(s). In forming the faux channel, the channel (e.g., the number of active channels 18) between the first source/drain region and the second source/drain region may be reduced. This reduction may be beneficial for one or more transistors in the low power device region of the semiconductor IC device, relative to transistors within high performance device region 113 in the same semiconductor IC device.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first source/drain region that is connected to a second source/drain region by one or more active channels;
a backside dielectric plug that is connected to the second source/drain region; and
a faux channel that is connected to the first source/drain region and that is connected to the backside dielectric plug.

2. The semiconductor IC device of claim 1, wherein the backside dielectric plug electrically isolates the second source/drain region from the faux channel.

3. The semiconductor IC device of claim 2, further comprising:
a conductive frontside contact that is connected to the second source/drain region.

4. The semiconductor IC device of claim 3, further comprising:
a conductive backside contact that is connected to the first source/drain region.

5. The semiconductor IC device of claim 4, further comprising:
a gate that is connected to the one or more active channels and that is connected to the faux channel.

6. The semiconductor IC device of claim 5, wherein the one or more active channels are vertically inline with the faux channel.

7. The semiconductor IC device of claim 6, wherein the faux channel is below the one or more active channels.

8. The semiconductor IC device of claim 7, wherein a bottom surface of the second source/drain region is above a bottom surface of the first source/drain region.

9. The semiconductor IC device of claim 8, further comprising an isolation layer between the gate and a backside interlayer dielectric (ILD) and wherein the backside dielectric plug is composed of a first dielectric material and the backside ILD is composed of a second dielectric material that is different from the first dielectric material.

10. The semiconductor IC device of claim 9, wherein the backside ILD is between a narrow region of the conductive backside contact and a narrow region of the backside dielectric plug.

11. The semiconductor IC device of claim 9, wherein a wide region of the conductive backside contact is directly coupled to a wide region of the backside dielectric plug.

12. A semiconductor integrated circuit (IC) device comprising:
a first transistor within a first region of the semiconductor IC device, the first transistor comprising a first source/drain region that is connected to a second source/drain region by a first group of active channels; and
a second transistor within a second region of the semiconductor IC device, the second transistor comprising:
a third source/drain region that is connected to a fourth source/drain region by a second group of active channels that has fewer active channels relative to the first group of active channels; a backside dielectric plug that is connected to the fourth source/drain region; and a faux channel that is connected to the third source/drain region and that is connected to the backside dielectric plug.

13. The semiconductor IC device of claim 12, wherein the backside dielectric plug electrically isolates the fourth source/drain region from the faux channel.

14. The semiconductor IC device of claim 13, further comprising:
a conductive frontside contact that is connected to the fourth source/drain region.

15. The semiconductor IC device of claim 14, further comprising:
a conductive backside contact that is connected to the third source/drain region.

16. The semiconductor IC device of claim 15, further comprising:
a gate that is connected to the second group of active channels and that is connected to the faux channel.

17. The semiconductor IC device of claim 16, wherein the second group of active channels is vertically stacked above the faux channel.

18. The semiconductor IC device of claim 17 wherein a bottom surface of the fourth source/drain region is above a bottom surface of the third source/drain region.

19. The semiconductor IC device of claim 18, further comprising an isolation layer between the gate and a backside interlayer dielectric (ILD) and wherein the backside dielectric plug is composed of a first dielectric material and the backside ILD is composed of a second dielectric material that is different from the first dielectric material.

20. A semiconductor integrated circuit (IC) device fabrication method comprising:
forming a backside dielectric plug opening within a backside interlayer dielectric that exposes a backside contact placeholder;
exposing a source/drain region by removing the backside contact placeholder;
removing a backside portion of the exposed source/drain region, wherein a bottom surface of the source/drain region is above a top surface of a bottommost channel; and
forming a backside dielectric plug within the backside dielectric plug opening, against the source/drain region, and against the bottommost channel, wherein the backside dielectric plug electrically isolates the bottommost channel from the source/drain region.
